(19) United States
(12) Patent Application Publication
(10) Pub. No.: US 2015/0001581 A1
(43) Pub. Date: Jan. 1, 2015

(54) SEMICONDUCTOR LIGHT RECEIVING ELEMENT AND LIGHT RECEIVER

(71) Applicants: Katsuya Oda, Tokyo (JP); Shinichi Saito, Tokyo (JP); Kazuki Tani, Tokyo (JP)

(72) Inventors: Katsuya Oda, Tokyo (JP); Shinichi Saito, Tokyo (JP); Kazuki Tani, Tokyo (JP)

(73) Assignee: HITACHI, LTD., Tokyo (JP)

(21) Appl. No.: 14/374,193

(22) PCT Filed: Jan. 23, 2012
(86) PCT No.: PCT/JP2012/000364

§ 371 Date: Jul. 23, 2014

(51) Int. Cl. H01L 31/107; H01L 31/028; H01L 31/0232

(52) U.S. Cl. CPC H01L 31/1075; H01L 31/02327; H01L 31/028
USPC 257/186

(57) ABSTRACT

An APD in which a first undoped semiconductor region and a second undoped semiconductor region having different semiconductor materials and arranged on an insulating film configure a photo-absorption layer and a multiplying layer, respectively, is employed, whereby crystalline of an interface between the photo-absorption layer and the multiplying layer becomes favorable, and a dark current caused by crystal defects can be decreased. Accordingly, light-receiving sensitivity of an avalanche photodiode can be improved. Further, doping concentration of the light-receiving layer and the multiplying layer can be made small. Therefore, a junction capacitance of the diode can be decreased, and a high-speed operation becomes possible.

### TECHNICAL FIELD

The present invention relates to improvement of characteristics of a semiconductor photodetector and an optical receiver.

### BACKGROUND ART

One of conventional semiconductor photodetectors is an avalanche photodiode that uses germanium as a light-receiving layer.

A conventional avalanche photodiode is described in NPL 1, for example. On a silicon substrate of NPL 1, a silicon layer serving as an electrode, and an undoped silicon layer serving as a multiplying layer of carriers are formed in order, an undoped single crystal germanium layer serving as a photo-absorption layer is then provided, and further, a p-type germanium layer serving as an electrode is formed. When light is absorbed in the undoped single crystal germanium layer serving as a photo-absorption layer, electrons and holes are generated by photon energy, and the electrons move to the multiplying layer and the holes move to the p-type electrode. When the electrons reach the undoped silicon layer that is a multiplying layer, the electrons are accelerated by an applied voltage, and the electrons sequentially generates carriers when scattered in the multiplying layer, so that a highly-sensitive semiconductor photodetector can be realized.

### CITATION LIST

### Non Patent Literature

NPL 1: Johnsi E. Bowers, Daoxin Dai, Yimin Kang, Mike Morse, “High-gain high-sensitivity resonant Ge/Si APD photodetectors”, Proceeding of SPIE, Vol. 7660, p. 76603H-1-8.

### SUMMARY OF INVENTION

### Technical Problem

A cross section structure of a conventional avalanche photodiode is illustrated in FIG. 11.

On a surface of a silicon substrate 101, a high-concentration n-type silicon layer 102, an undoped silicon layer 103, a p-type silicon layer 104, an undoped germanium layer 105, and a high-concentration n-type germanium layer 106 are deposited in order. Next, after a portion other than a device region is etched and removed, the whole is covered with an insulating film 107, contact holes serving as electrodes are formed, and electrodes 109 and 108 are formed to be in contact with the high-concentration n-type silicon layer 102 and the high-concentration p-type germanium layer 106, respectively.

When a multi-layered structure of the silicon layers and the undoped germanium layers is deposited in order by epitaxial growth, a large distortion is caused due to lattice mismatch between a lattice constant of silicon and a lattice constant of germanium. As a result, dislocation may be caused in the vicinity of an interface between germanium and silicon. Therefore, many crystal defects are caused in the vicinity of an interface between the undoped germanium layer 105 and the p-type silicon layer 104. As a result, the carriers generated by absorbing the light in the undoped germanium layer 105 are recombined before reaching the p-type silicon layer 104, and a dark current is substantially increased. Therefore, light-receiving sensitivity of the avalanche photodiode is decreased.

As a method of decreasing the crystal defects, there is a method of performing annealing at a high temperature after forming the undoped germanium layer 105. However, in this method, dopants included in the high-concentration n-type silicon layer 102 and the p-type silicon layer 104 are diffused by the annealing to the undoped silicon layer 103 and the undoped germanium layer 105 are doped, and the dopant concentration is increased. The increase in the doping concentration incurs an increase in junction capacitance, resulting in deterioration of device operation characteristics (high-speed responsiveness).

An objective of the present invention is to improve light-receiving sensitivity and responsiveness of a semiconductor photodetector and an optical receiver.

### Solution to Problem

While the present application includes a plurality of means capable of achieving the above objective, one representative means is as follows.

There is a means including: an insulating film formed on a substrate; a first undoped semiconductor region and a second undoped semiconductor region provided on the insulating film; an n-type electrode electrically connected to the first undoped semiconductor region; and a p-type electrode electrically connected to the second undoped semiconductor region, wherein the first undoped semiconductor region and the first undoped semiconductor region are configured from different semiconductor materials, and are arranged in a substrate in-plane direction.

### Advantageous Effects of Invention

According to the present invention, light-receiving sensitivity and responsiveness of a semiconductor photodetector and of an optical receiver using the same can be improved.

### BRIEF DESCRIPTION OF DRAWINGS

FIG. 1 is a cross sectional view of an avalanche photodiode according to Embodiment 1.

FIGS. 2(a) to 2(c) are manufacturing process diagrams of the avalanche photodiode according to Embodiment 1.

FIGS. 3(a) to 3(c) are manufacturing process diagrams of the avalanche photodiode according to Embodiment 1.

FIG. 4 is a bird's-eye view of the avalanche photodiode according to Embodiment 1, as viewed from a surface side.

FIG. 5 is a cross sectional view of an avalanche photodiode according to Embodiment 2.

FIGS. 6(a) to 6(d) are manufacturing process diagrams of the avalanche photodiode according to Embodiment 2.

FIG. 7 is a bird's-eye view of a surface incident type avalanche photodiode array according to Embodiment 3, as viewed from a surface.

FIG. 8 is a cross sectional view of an avalanche photodiode according to Embodiment 4.

FIG. 9 is a bird's-eye view of an optical transmitter/receiver according to Embodiment 5.

FIG. 10 is a bird's-eye view of an optical transmitter/receiver according to Embodiment 6.

FIG. 11 is a cross sectional view of a conventional avalanche photodiode.

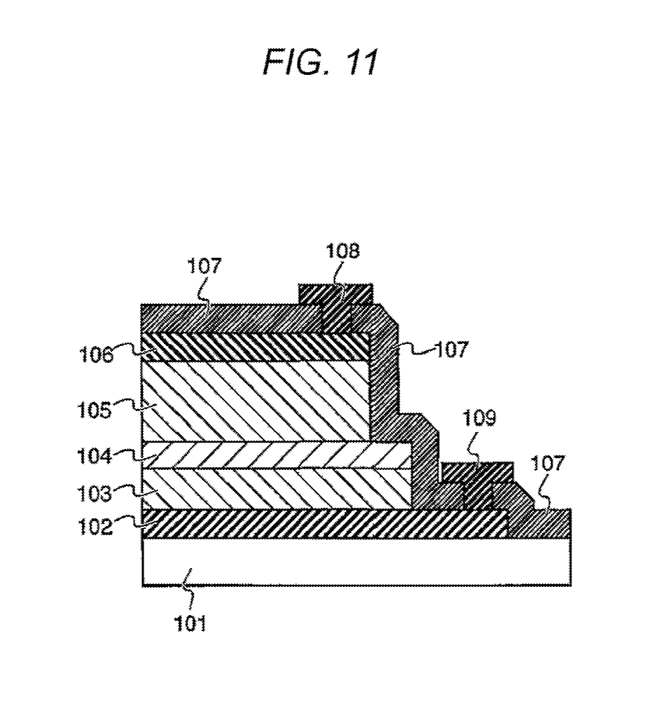

### DESCRIPTION OF EMBODIMENTS

Hereinafter, embodiments using avalanche photodiodes as semiconductor photodetectors will be described.

### Embodiment 1

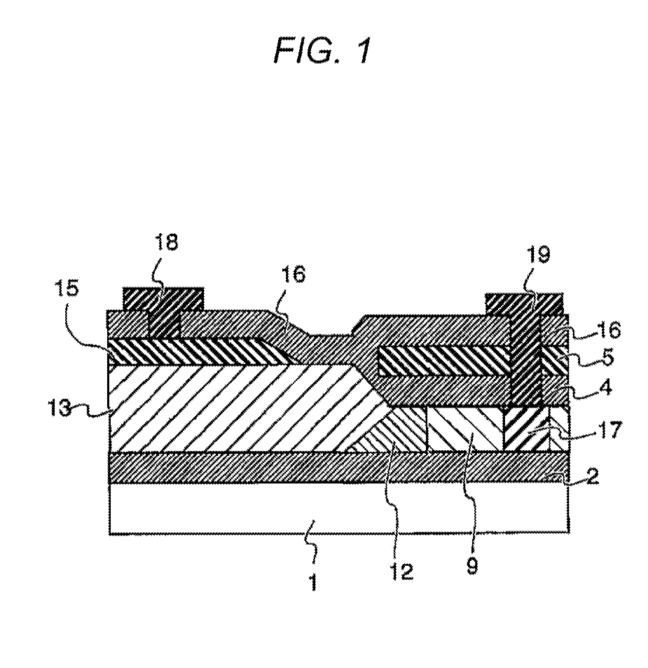

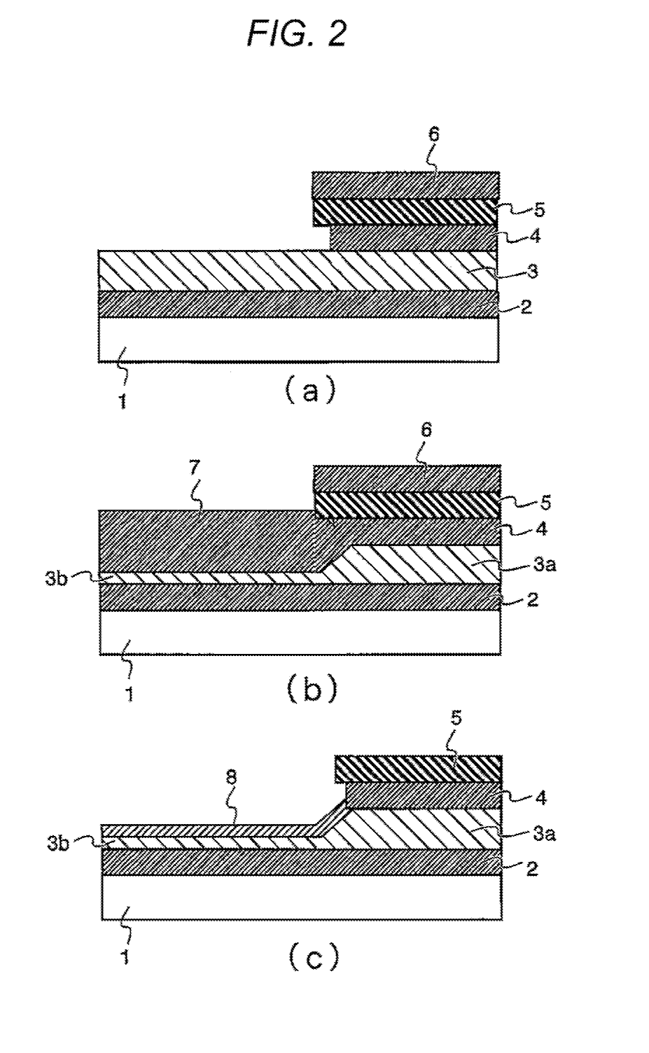

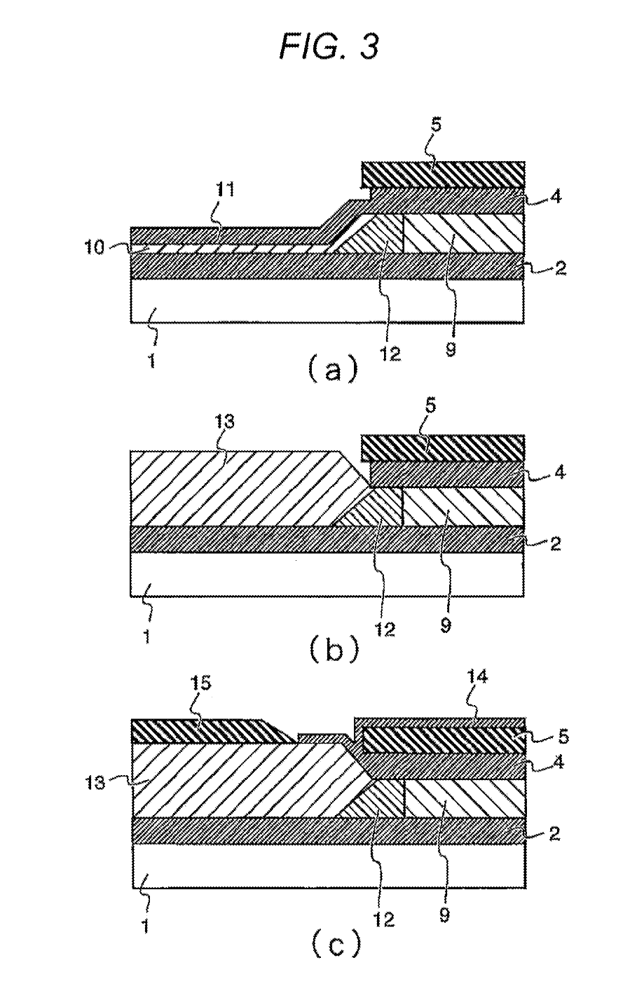

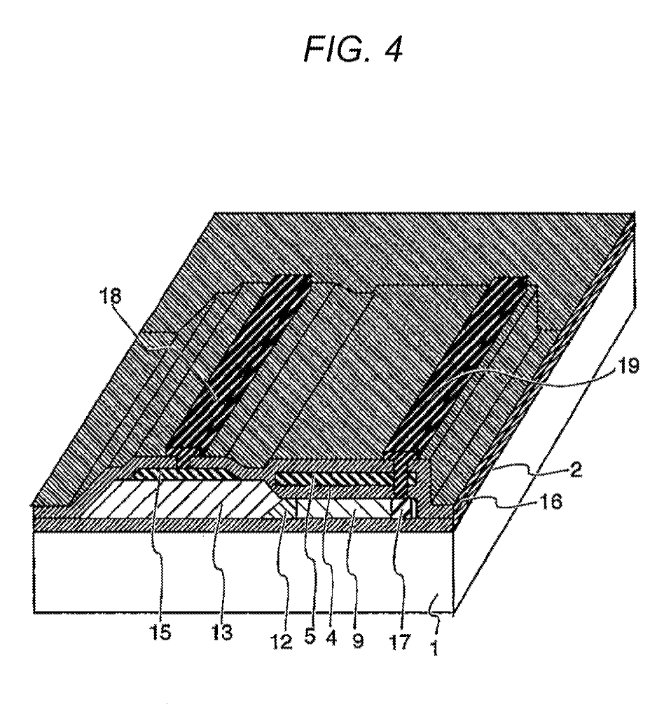

Embodiment 1 will be described with reference to FIGS. 1, 2(a) to 2 (c), 3(a) to 3(c), and 4. FIG. 1 is across sectional view of an avalanche photodiode according to Embodiment 1. FIGS. 2(a) to 2(c) and 3(a) to 3(c) are manufacturing process diagrams of the avalanche photodiode of Embodiment 1. FIG. 4 is a bird's-eye view of the avalanche photodiode according to Embodiment 1, as viewed from a surface side.

As a semiconductor substrate, an SOI substrate in which a layered structure of an insulating film 2 and an undoped single crystal silicon layer 3 is formed on a surface side of a silicon substrate 1 is used. The film thickness of the undoped single crystal silicon layer 3 is from 10 nm to 1 μm, both inclusive. A lower limit value 10 nm is set to have a resistance to the degree that the undoped single crystal silicon layer 3 practically functions as a multiplying layer, and an upper limit value 1 μm is set to obtain a practical capacitance. An insulating film 4 made of a silicon oxide film, an insulating film 5 made of a silicon nitride film, and an insulating film 6 made of a silicon oxide film are formed on the undoped single crystal silicon layer 3, and an opening of an insulating film is then provided in a region that is to be a photo-absorption region of the avalanche photodiode (FIG. 2(a)).

Next, oxidation of the undoped single crystal silicon layer 3 exposing in the opening of the insulating film is performed (FIG. 2(b)). This oxidation process enhances controllability by making the single crystal silicon layer 3 thin only in a region 3b so that the whole silicon remained on a region that is to serve as a receiver later. Note that, principally, in the semiconductor photodetector, a next process can be performed with the single crystal silicon layer 3 as it is without performing the oxidation. Note that, if the portion 3b where the single crystal silicon layer 3 is made thin is made too thin, a portion where the entire undoped single crystal silicon 3 is oxidized may be caused due to influence of variation of the film thickness of the original undoped single crystal silicon layer 3. Therefore, the film thickness of the undoped single crystal silicon layer 3b is at least 5 nm or more.

Next, a silicon oxide film 7 is etched and removed, and the undoped single crystal silicon layer 3b is exposed. Then, an undoped single crystal silicon-germanium layer 8 is formed (FIG. 2(c)). For example, when the oxide film is removed with a hydrofluoric acid aqueous solution, the silicon substrate surface is cleaned with pure water immediately after the removal, so that the silicon substrate surface is covered with hydrogen atoms. In this state, silicon atoms existing on an outermost surface of the substrate are combined with hydrogen. Therefore, a native oxide is less likely to be formed on the surface from when the substrate cleaning is performed to when growing is started. The substrate surface is terminated by hydrogen with the cleaning, and further, the substrate is transferred in pure nitrogen so as to prevent a native oxide from being further formed on the surface and to prevent a contamination from adhering to the substrate surface after cleaning of the substrate. The same applies to the following embodiments regarding cleaning of a substrate and a transfer method performed before epitaxial growth.

Next, the substrate subjected to the cleaning is set inside a load-lock chamber of an epitaxial growth apparatus, and evacuation of the load-lock chamber is started. When the evacuation of the load-lock chamber is completed, the substrate is transferred to a growth chamber via a transfer chamber. To prevent a contamination from adhering to the substrate surface, it is desirable to cause pure N2 or H2 to flow in the transfer chamber and in the growth chamber or to cause the chambers to be in a high vacuum state or in an ultrahigh vacuum state. When the chambers are made to be in a vacuum state, it is favorable to set the pressure to about 1×10⁻⁵ Pa or less. Further, to prevent occurrence of crystal defects due to taking in of oxygen and carbon to the single crystal layer formed in the growth chamber, it is necessary to prevent oxygen, water, or a gas containing an organic contamination from being mixed in to the transfer chamber and the growth chamber. Therefore, it is desirable to transfer the silicon substrate 1 in a state where pure N2 is being supplied, or in a state where the pressure in the load-lock chamber becomes about 1×10⁻⁵ Pa or less when the transfer is performed in a vacuum. The formation of an oxide film and the adhering of a contamination on the surface during transfer cannot be completely prevented even if the surface of the undoped single crystal silicon layer 3 is terminated by hydrogen. Therefore, the surface is cleaned before the epitaxial growth. As a cleaning method, for example, a method of heating the silicon substrate 1 in a vacuum to remove the native oxide on the silicon surface by a reaction of a formula (1) is possible.

Si+SiO₂→2SiO↑ (1)

Further, the cleaning of the substrate surface can be performed by heating of the substrate in a state where pure hydrogen is being supplied to the growth chamber. In the cleaning by heat in a vacuum described above, when the substrate temperature becomes about 500° C. or more, the hydrogen that have terminated the substrate surface is desorbed, and exposed silicon atoms on the substrate surface, and water and hydrogen contained in an atmosphere in the growth chamber react with each other and the substrate surface is reoxidized. Then, by reducing of the oxide film again, unevenness of the substrate surface is increased with cleaning, and uniformity and crystalline of the epitaxial growth performed later are deteriorated. Further, at the same time, carbon dioxide and an organic gas contained in the atmosphere in the growth chamber adhere to the surface. Therefore, deterioration of the crystalline of the epitaxial growth layer due to a carbon contamination also occurs. Meanwhile, when the silicon substrate is heated in a state where hydrogen is supplied, a pure hydrogen gas is always being supplied even if hydrogen is desorbed from the substrate surface at a temperature of 500° C. or more. Therefore, silicon on the substrate surface and hydrogen repeat combination and desorption. As a result, the silicon on the surface is less likely to be reoxidized, the unevenness on the surface does not occur during cleaning, and a pure surface state can be obtained.

To perform cleaning in a hydrogen atmosphere, first, a hydrogen gas is supplied to the growth chamber. At this time, to prevent desorption of hydrogen from the substrate surface before the hydrogen gas is supplied, it is favorable to set the substrate temperature to be lower than 500° C. at which hydrogen is desorbed from the substrate. Further, the flow rate of the hydrogen gas is set to 10 ml/min or more so that the gas can be supplied with good controllability, and is favorably set to 100 l/min or less so as to safely process an exhaust gas. At this time, a lower limit of a partial pressure of the hydrogen gas in the growth chamber is 10 Pa so that the gas can be uniformly supplied to the substrate surface, and an upper limit may just be an atmospheric pressure in order to keep safety of the apparatus. After the hydrogen gas is supplied, the substrate is heated to a cleaning temperature. Any mechanism or structure may be employed for a heating method as long as no contamination is caused on the substrate and no extreme temperature difference is caused within the substrate at the heating. For example, induction heating that applies a high frequency to a work coil to perform heating, or heating by a resistance heater can be applied. Further, especially, as a method that enables temperature control in a short time, a heating method using radiation from a lamp can be used. These heating methods are not only applied to the cleaning, and can be applied to heating at growing of single crystal described below.

After the substrate is heated to the cleaning temperature, the substrate is heated for a predetermined time, so that the native oxide and the contamination on the surface can be removed. For example, the cleaning temperature may just be 600° C. or more as a temperature to obtain effect of cleaning. However, to decrease influence on a surface structure formed before the epitaxial growth, it is necessary to set the temperature to 900° C. or less. Further, removal efficiency of the native oxide and the contamination on the substrate surface vary according to the cleaning temperature. The effect can be obtained in a short time as the temperature is higher. When the cleaning temperature is 700° C., the cleaning effect is small and thus the cleaning time requires 30 minutes. Meanwhile, when the cleaning time is 900° C., the cleaning time may just be 2 minutes or more. As the influence on the surface structure, consider characteristic variation due to diffusion of the dopants in the substrate, for example. To suppress the diffusion of the dopants, it is desirable to set the cleaning temperature to about 800° C. or less, and the cleaning time of this time may just be about 10 minutes.

Further, as a method that enables a decrease in the cleaning temperature, cleaning using atomic hydrogen can be performed. This method can cause a reduction reaction of oxygen without increasing the substrate temperature by irradiating the substrate surface with active hydrogen atoms, and the cleaning effect can be obtained at room temperature. As a method of generating atomic hydrogen, a method of irradiating a filament made of tungsten or the like heated at a high temperature with hydrogen gas to thermally dissociating hydrogen molecules, a method of generating plasma in a hydrogen gas to electrically dissociating hydrogen molecules, a method of generating hydrogen by irradiation of ultraviolet rays, or the like is possible. Note that, in these cases, it is necessary to pay enough attention to occurrence of a metal contamination from the filament or from a periphery of the electrode that generates plasma, and occurrence of a contamination from a quarts component by plasma. In both cases, it is extremely difficult to generate a large volume of hydrogen atoms. Therefore, molecules of a certain rate in the hydrogen gas are dissociated into an atomic state, and the substrate surface is irradiated with the dissociated molecules, so that the temperature can be decreased. For example, to have the cleaning time within 10 minutes, the cleaning temperature may just be set to 650° C.

Further, the native oxide film on the surface can be removed by a chemical reaction that does not require heating. For example, by supplying of an HF gas, the oxide film is removed by an etching reaction. Therefore, the cleaning can be performed at room temperature.

Description of the cleaning before the epitaxial growth has been made. The same applies to other embodiments regarding the cleaning method.

After the cleaning is completed, the substance temperature is decreased to a temperature at which the epitaxial growth is performed, and a time to stabilize the substrate temperature is provided at the temperature at which the epitaxial growth is performed. In the step to stabilize the temperature, it is desirable to continuously supply a hydrogen gas in order to keep the silicon substrate surface after the cleaning in a pure state. However, the hydrogen gas has an effect to cool the substrate surface, and thus the substrate surface temperature may be changed according to a flow rate of the gas if the heating condition is the same. Therefore, even if the temperature is stabilized in a state where the hydrogen gas is being supplied at a flow rate that is substantially different from a total flow rate of the gas used in the epitaxial growth, the substrate temperature may be substantially changed as the flow rate of the gas is changed at the time when the epitaxial growth is started. To avoid this phenomenon, in the step to stabilize the substrate temperature, it is desirable to use the hydrogen flow rate, the value of which is the same value as the total flow rate of the gas used in the epitaxial growth. Further, it is not necessarily provided the step to stabilize the temperature after the substrate temperature is decreased to the epitaxial growth temperature. It is just favorable, when adjusting the flow rate of the hydrogen gas while decreasing the substrate temperature, and if the flow rate of the hydrogen gas becomes equal to the flow rate of the growth temperature at the time when the substrate temperature becomes the epitaxial growth temperature.

Next, the epitaxial growth of the single crystal silicon-germanium layer 8 is started by supplying of source gases of an epitaxial layer. As the source gases used here, a compound made of silicon or germanium, and hydrogen, chlorine, fluorine, or the like can be used. Examples of the source gas of silicon include monosilane (SiH₄), disilane (Si₂H₆), dichlorosilane (SiH₂Cl₂), trichlorosilane (SiHCl₃), and tetrachlorosilicon (SiCl₄). Further, examples of the source gas of germanium include monogermane (GeH₄), digermane (Ge₂H₆), and germanium tetrachloride (GeCl₄).

Here, when the undoped single crystal silicon-germanium layer 8 is deposited not only on the undoped single crystal silicon layer 3b but also on the insulating film 5, the whole portion deposited on the insulating film 5 needs to be oxidized in the next oxidation process. However, at that time, a gas or a particle may occur in the oxidation stage. Therefore, it is favorable not to allow the undoped silicon-germanium to be deposited on a side wall of the insulating film 4 or on the insulating film 5, and to allow the undoped silicon-germanium to be selectively epitaxially grown only on the undoped single crystal silicon layer 3b. The source gas of silicon and surface molecules react with each other on the silicon film and reactions like below are caused. For example, following reduction reactions are caused:

Si₂H₆+2SiO₂→4SiO↑+3H₂↑ (2)

where disilane (Si₂H₆) is used as the source gas of silicon;

SiH₄+SiO₂→2SiO↑+2H₂↑ (3)

where monosilane (SiH₄) is used as the source gas of silicon; and

SiH₂Cl₂+SiO₂→2SiO↑+2HCl↑ (4)

where dichlorosilane (SiH₂Cl₂) is used as the source gas.

Further, the same applies to germane (GeH₄) that is the source gas of germanium. A reduction reaction regarding germanium is:

GeH₄+SiO₂→SiO↑+GeO↑+2H₂↑ (5).

The above reduction reactions are apart of a large number of reactions. In addition to the above reactions, a reduction reaction between radical molecules generated as the source gas is decomposed and having high energy, and the oxide film also exists. As a result, etching by the reduction reactions and deposition caused by decomposition of the material concurrently proceed on the oxide film, and the magnitude relationship between the etching and the deposition is changed depending on the growth temperature and the pressure.

Further, when a silicon nitride film is used as the insulating film 5, the above reduction reactions cannot be used. Therefore, a halogen gas, such as a chlorine gas (Cl) or a hydrogen chloride gas (HCl), is added to the source gas, and the etching of the silicon layer itself is performed. A reaction thereof includes:

Si+2Cl₂→SiCl₄↑ (6)

Si+2HCl→SiH₂Cl₂↑ (7)

As a result of the concurrent proceeding of the reactions, silicon is not deposited on the silicon nitride film in a state where selectivity is maintained.

A composition ratio of germanium in the undoped single crystal silicon-germanium layer 8 can be controlled by changing of a flow ratio of the source gas of silicon and the source gas of germanium. To select only silicon in a subsequent process, it is more favorable if the germanium composition ratio is higher. However, if the germanium composition ratio is too high, surface morphology is deteriorated, and crystal defects are generated. Therefore, in reality, the germanium composition ratio may just be about 35%. Further, the film thickness of the undoped single crystal silicon-germanium layer 8 may just be a critical film thickness or less with which the crystalline according to the germanium composition ratio can be maintained. To be specific, if the germanium composition ratio is 35%, the film thickness is about 100 nm or less, and if the germanium composition ratio is 20%, the film thickness is 1 μm or less. At this time, to form the undoped single crystal silicon-germanium layer 8 with good crystalline, the epitaxial growth temperature is decreased. At this time, it is favorable if the source gases, such as disilane or monosilane, and germane that have high reactivity and can decrease the growth temperature, are used, the temperature range is 500° C. or more, at which the source gases start thermal decomposition, and an upper limit is 650° C. or less in which good surface morphology is maintained. It is favorable if the growth pressure is, in the temperature range, favorably 0.1 Pa or more, at which the growth speed is limited by a reaction on the surface, and an upper limit is the atmospheric pressure or less so that the safety of the epitaxial growth apparatus is secured.

Next, oxidation of the undoped single crystal silicon-germanium layer 8 is performed. In this process, silicon is preferentially oxidized when silicon-germanium are oxidized. This process forms an undoped single crystal germanium layer 10 under a silicon oxide film 11 from the undoped single crystal silicon-germanium layer 8 using a phenomenon called oxidation concentration where the germanium composition ratio in the silicon-germanium layer 8 becomes high. Wet oxidation or dry oxidation may be employed, similarly to oxidation of silicon. However, it is necessary to determine an upper limit of the oxidation temperature according to the Ge composition ratio. While the melting point of silicon is about 1410° C., the melting point of Ge is about 940° C. Therefore, the melting points get lowered as the oxidation proceeds and the Ge composition ratio becomes higher.

Further, although not illustrated in FIG. 2(c), when Ge contained in the undoped single crystal silicon-germanium layer 8 is directly in contact with an oxidation atmosphere, unstable substances, such as GeOx, may be generated and desorbed. Therefore, it is desirable to form an undoped single crystal silicon layer on the surface of the undoped single crystal silicon-germanium layer 8. At this time, to reliably protect the surface of the undoped single crystal silicon-germanium layer 8, high uniformity of the film thickness is required for the undoped single crystal silicon layer. The film thickness of the undoped single crystal silicon layer may just be 1 nm or more as long as a uniform film thickness can be obtained. With the thickness, the stable undoped single crystal silicon layer can cover the outermost surface. Further, if the undoped single crystal silicon layer is too thick, a time to perform the oxidation concentration becomes long, and the throughput is remarkably decreased. Therefore, the film thickness of the undoped single crystal silicon layer 8 may just be about 50 nm or less. When the undoped single crystal silicon-germanium layer 8 is oxidized, the silicon oxide film 11 is formed on the surface, and the Ge composition ratio in the undoped single crystal silicon-germanium layer 8 becomes high. Therefore, in a case where the oxidation is started at 1050° C., when the Ge composition ratio is increased to about 60%, the temperature is close to the melting point. Therefore, the oxidation can be continued while the crystal is maintained by decreasing of the oxidation temperature to 900° C. Ideally, when all of silicon contained in the undoped single crystal silicon-germanium layer 8 have been oxidized, the undoped single crystal germanium 10 is formed. In reality, it is difficult to selectively and completely oxidize only the silicon due to ununiformity of the film thickness of the undoped single crystal silicon-germanium layer 8 and of the germanium composition ratio. Further, if oxidation is continued after all of silicon in the undoped single crystal silicon-germanium layer 8 has been oxidized, germanium begins to be oxidized and unstable GeOx is formed and defects are generated. Therefore, excessive oxidation should be avoided. Even before the silicon in the undoped single crystal silicon-germanium layer 8 is fully oxidized, silicon is preferentially oxidized at the interface between the silicon oxide film 11 and the undoped single crystal silicon-germanium layer 8, and the Ge composition ratio becomes high. Therefore, the undoped single crystal germanium layer 10 formed in the oxidation concentration indicates a state in which the germanium composition ratio on the surface is approximately 90% or more. In the following embodiments, the germanium composition ratio in the undoped single crystal germanium layer 10 after the oxidation concentration is similar. After a mask is formed using photolithography after the oxidation concentration, p-type impurities are implanted into a vicinity of an interface between the undoped single crystal silicon layer 9 and the undoped single crystal germanium layer 10, and annealing is performed to activate the p-type impurities, so that a p-type silicon region 12 is formed (FIG. 3(a)).

Further, it is favorable to apply tensile strain to the undoped single crystal germanium layer 10 formed by performing of the oxidation concentration of germanium from the undoped single crystal silicon-germanium layer 8 on the silicon oxide film 2. While the silicon oxide film 2 has a thermal expansion coefficient of 0.5×10⁻⁶/° C., and is not much expanded even if oxidation, which is high-temperature annealing, is performed, the thermal expansion coefficient of germanium is 6.1×10⁻⁶/° C., which is larger than that of the oxide film. Therefore, the germanium layer is expanded in a state where oxidation is performed. In this high-temperature state, the strain of the single crystal germanium layer 10 is relaxed. However, the oxide film is not much contracted in the process of cooling after the oxidation. In contrast, the single crystal germanium layer 10 is contracted in a large way, and thus a portion that has been in contact with the silicon film cannot be contracted more than that, and tensile strain is remained inside. If the tensile strain is remained in the single crystal germanium layer 10, a band gap is decreased. Therefore, when the distorted single crystal germanium layer 10 is used as an absorption layer of light, the sensitivity to light having low energy, that is, light having a long wavelength, is improved. As a result, sufficient light-receiving sensitivity can be obtained with respect to the light having a wavelength of 1.55 μm, which is typically used in the optical communication.

Next, the silicon oxide film 11 formed by the oxidation concentration is etched and removed, an undoped single crystal germanium layer is regrown on the exposed undoped single crystal germanium layer 10, and an undoped single crystal germanium layer 13 is formed on the silicon oxide film 2. As the source gas used here, a compound made of germanium and hydrogen, chlorine, fluorine, or the like can be used. For example, examples include monogermane (GeH₄), digermane (Ge₂H₆), and germanium tetrachloride (GeCl₄). The use method is similar in other gases. Hereinafter, description will be given regarding a case where monogermane is used as the source gas. The temperature range in which the epitaxial growth is performed is 300° C. or more, at which monogermane causes a reaction on the substrate surface. Further, it is necessary to perform growth at the melting point of germanium or less, and thus the upper limit of the growth temperature may just be 940° C. or less. In this temperature range, the growth pressure may just be 0.1 Pa or more in which the growth speed is limited by the reaction on the surface, and the upper limit may just be 10000 Pa or less at which the reaction in a vapor phase begins to occur. Further, by use of the reduction reaction of germane and a halogen etching gas, similarly to the case of the undoped single crystal silicon-germanium layer 8, germanium is not deposited on the side wall of the insulating film 4 and on the surface of the insulating film 5, and the undoped single crystal germanium is selectively grown only on the undoped single crystal germanium layer 10, so that the undoped single crystal germanium layer 13 is formed. The same applies to the embodiments below regarding the epitaxial growth condition of the undoped single crystal germanium.

Then, the insulating film 14 is deposited on the surface, an opening for connecting with an electrode is formed only in the undoped single crystal germanium layer 13, and the high-concentration p-type single crystal germanium layer 15 is formed only in the opening. Note that, to perform p-type doping, the p-type doping gas may just be added to the source gas of germanium at the same time. As the p-type doping gas, a compound made of a group III element, and hydrogen, chlorine, fluorine, or the like can be used, and an example includes diborane (B₂H₆). The condition to perform the epitaxial growth is similar to that of the undoped germanium. The doping concentration can be controlled by a flow rate of a doping gas, and when p-type doping of 1×10²⁰ cm⁻³ is performed, for example, the flow rate of diborane may just be 0.1 ml/min. (FIG. 3 (b)).

Further, the insulating film 16 is formed on the surface, openings for forming electrodes are provided, and the electrodes are formed in respective regions. To be specific, an electrode material, such as nickel, is deposited, and annealing is performed, so that germanide that is an alloy of metal and germanium is formed, and the p-type electrode 18 having a small contact resistance is formed (FIG. 1). Note that the high-concentration p-type single crystal silicon layer is provided on the high-concentration p-type single crystal germanium layer 15, and the p-type electrode 18 may be formed with silicide.

Further, the insulating films 4, 5, and 16 are partially removed and an opening is provided, n-type dopants are implanted into the undoped single crystal silicon layer 9 with high concentration, through the opening, a high-concentration n-type silicon layer 17 is provided, and metal and the high-concentration n-type silicon are caused to react to form the silicide, so that an n-electrode 19 having a low contact resistance is realized.

As described above, for easy description, the structure having the high-concentration p-type single crystal germanium layer 15, the undoped single crystal germanium layer 13, the high-concentration p-type single crystal silicon region 12, the undoped single crystal silicon layer 9, and the high-concentration n-type silicon layer 17 has been described according to existence of doping. However, in reality, the dopant and germanium are diffused due to annealing to no small extent. Therefore, a structure in which transition regions where profiles of the doping concentration and the germanium composition ratio are gently changed exist in interfaces is also included. Further, the doping concentration in the undoped layer is desirably as low as possible in order to decrease the capacity. However, a background of the dopant always exists in the epitaxial growth, and thus a state where the doping concentration is 1×10¹⁷ cm⁻³ or less is an undoped state. The same applies to other embodiments.

An operation of the avalanche photodiode of Embodiment 1 will be described with reference to FIG. 4. When light is incident on the undoped single crystal germanium layer 13 that is to serve as a receiver from an optical fiber or a waveguide, holes and electrons are generated, and the holes and the electrons are diffused toward the p-electrode 18 and the n-electrode 19, respectively. Reverse biases are applied to the p-type electrode 18 and the n-type electrode 19, and a large electric field is generated in the undoped single crystal silicon layer 9. Therefore, the electrons are accelerated by the electric field when having reached the undoped single crystal silicon layer 9 that is the multiplying layer, and generate carriers one after another. The carriers travel parallel to the substrate.

As described above, according to the present embodiment, the undoped single crystal silicon 9 and the undoped single crystal germanium 13 can be formed on the silicon oxide film 2. Therefore, an interface between a single crystal germanium and a single crystal silicon having good crystalline can be formed. The conventional dark current due to crystal defects can be substantially decreased, and the light-receiving sensitivity can be improved.

Further, a junction area of the avalanche photodiode is determined by junction areas of the undoped single crystal silicon and the undoped single crystal germanium. Therefore, the size can be substantially reduced, compared with a conventional device size formed by photolithography and etching. Therefore, the high frequency characteristic can be considerably improved by the decrease in the junction capacitance.

### Embodiment 2

A difference between Embodiment 2 and Embodiment 1 is a method of forming a p-type silicon region. In Embodiment 2, the p-type silicon region is formed only by epitaxial growth.

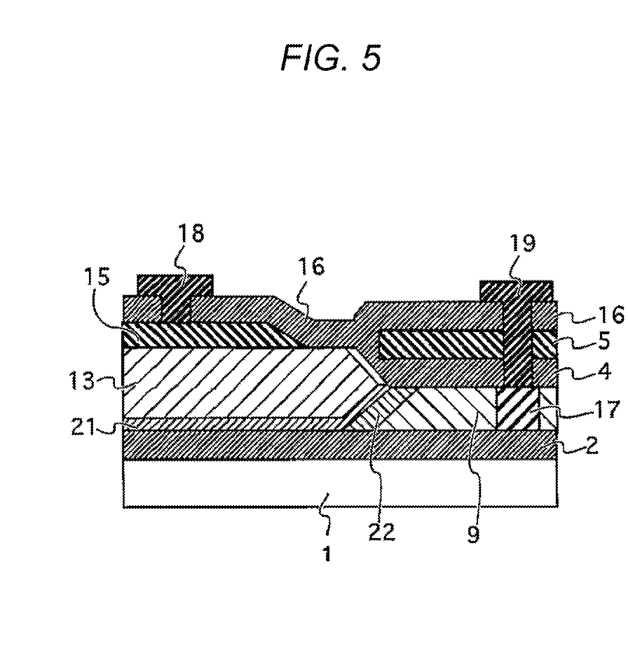

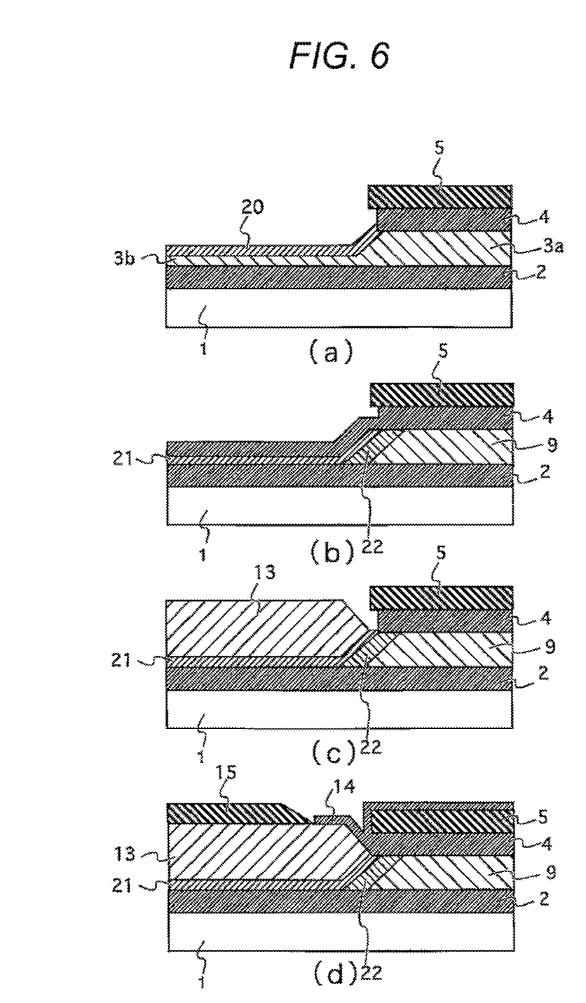

FIG. 5 is a cross sectional view of an avalanche photodiode according to Embodiment 2. FIGS. 6(a) to 6(d) are manufacturing process diagrams of the avalanche photodiode according to Embodiment 2. The same reference signs as Embodiment 1 indicate the same configurations.

Similarly to Embodiment 1, after undoped single crystal silicon layers 3a and 3b are formed, a p-type silicon-germanium layer 20 is formed by epitaxial growth (FIG. 6(a)). As for p-type doping, similarly to the formation of the high-concentration p-type germanium layer of Embodiment 1, a p-type doping gas is applied to source gases of silicon and germanium. The doping concentration can be controlled by a flow rate of the doping gas, and to perform p-type doping of 1×10¹⁹ cm⁻³, a flow rate of diborane may just be 0.01 ml/min.

Next, by performing of oxidation concentration, dopants in the p-type silicon-germanium layer 20 are diffused in an undoped single crystal silicon layer 3a by annealing during oxidation, and a p-type single crystal silicon region 22 is formed, at the same time as a p-type germanium layer 21 is formed (FIG. 6(b)). Subsequent processes are similar to Embodiment 1, an undoped single crystal germanium layer 13 is grown (FIG. 6(c)), an insulating film and an opening are formed on/in a surface, and a p-type germanium layer 15 for forming a p-type electrode is formed (FIG. 6(d)).

According to the present embodiment, not only a similar effect to Embodiment 1 can be obtained, but also improvement of throughput and a decrease in cost by simplification of processes can be achieved because photolithography and ion implantation are not necessary to form the p-type silicon region.

### Embodiment 3

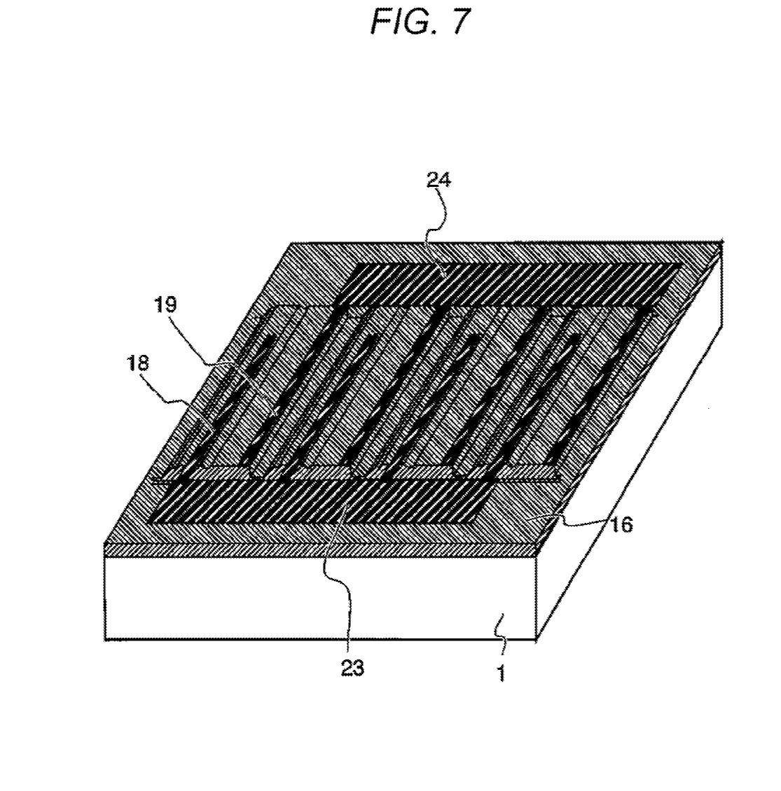

FIG. 7 is a bird's-eye view of a surface incident type avalanche photodiode array as viewed from a surface, illustrating Embodiment 3. Embodiment 3 is an avalanche photodiode array in which a plurality of avalanche photodiodes of Embodiment 1 or 2 is arranged in parallel, and an incident direction of light is made perpendicular to a substrate.

A plurality of undoped single crystal germanium layers that are to serve as photo-absorption layers and undoped single crystal silicon layers that are to serve as multiplying layers, which are configuration elements of the avalanche photodiode, are alternately arranged and formed. When a p-type electrode 18 and an n-type electrode 19 are formed, drawing out directions of the electrodes are changed. A p-type electrode 23 and an n-type electrode 24 are formed at opposite sides to each other. In doing so, a large-area detector can be formed without increasing a distance from holes and electrons generated by light incident on the avalanche photodiode to a multiplying layer where the holes and electrons reach. Therefore, an optical fiber can be arranged in a direction perpendicular to the substrate. By increasing of the parallel number, an avalanche diode having a large area, for example, 100 to 500 μm, can be realized.

Embodiment 3 not only obtains a similar effect to Embodiments 1 and 2, but also realizes a surface incident type avalanche photodiode. Therefore, the alignment of when light is incident from an optical fiber becomes easy.

### Embodiment 4

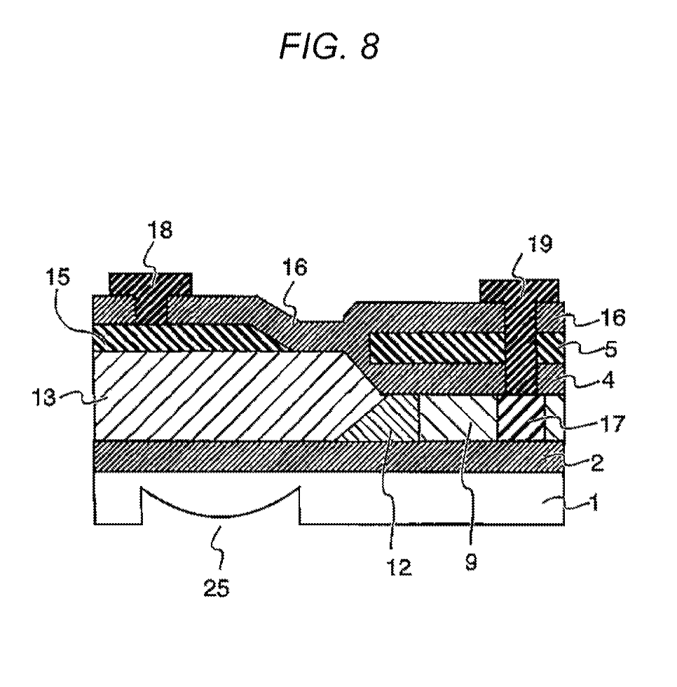

In Embodiment 4, a lens is formed on a back surface of a silicon substrate 1 of an avalanche photodiode of Embodiment 1 or 2, and the light can be incident from the back surface. FIG. 8 is a cross sectional view of an avalanche photodiode according to Embodiment 4.

After the avalanche photodiode of Embodiment 1 or 2 is formed, a lens 25 is formed by photolithography and etching on a region of the back surface of the silicon substrate 1, the region facing a signal crystal germanium layer 13 that is to serve as a receiver. By forming of the integrated lens, the beam size of light incident from the back surface can be stopped down, and alignment with an optical fiber becomes easy.

Embodiment 4 can not only obtain a similar effect to Embodiments 1 and 2, but also realize a back surface incident type avalanche photodiode. Therefore, when the present optical receiver is used alone, the alignment of when light is incident from the optical fiber becomes easy.

### Embodiment 5

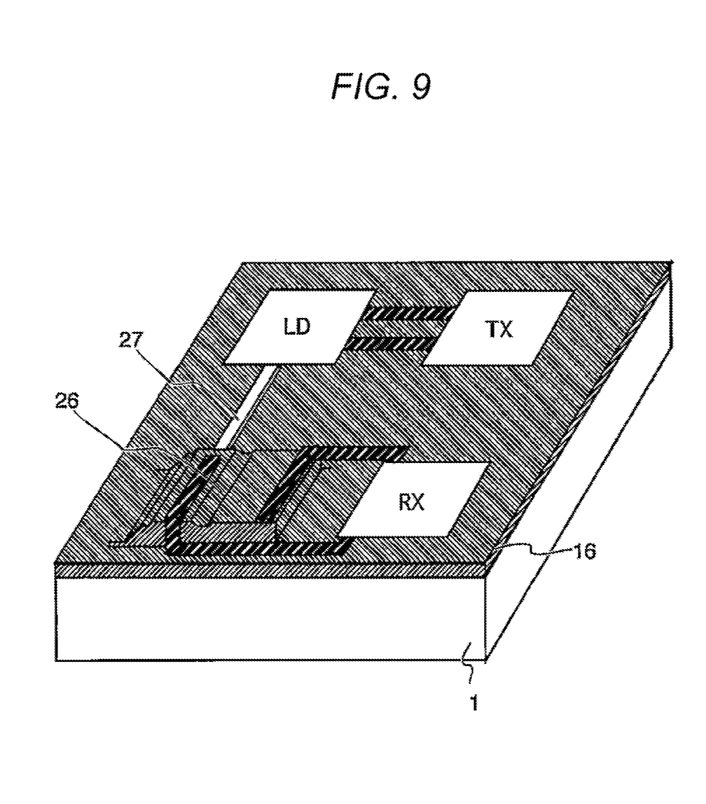

In Embodiment 5, a digital signal processing circuit and a light source are integrated on a substrate on which an avalanche photodiode 26 of Embodiment 1 or 2 is formed. FIG. 9 is a bird's-eye view of an optical receiver. To be specific, a laser diode LD as the light source and the avalanche photodiode 26 are integrated on a silicon substrate 1, and these devices are connected by a silicon waveguide 27, so that the structure does not require automatic alignment.

Further, as signal processing circuits, a transmission circuit TX is electrically connected to the laser diode LD as the light source, and a reception circuit RX is electrically connected to the avalanche photodiode 26, respectively. Then, these signal processing circuits are integrated on the substrate, so that high-speed optical transmission in a chip can be realized. Here, the transmitter circuit TX includes a driver amplifier for driving the laser in addition to the signal processing. Similarly, the receiver circuit RX includes a transimpedance amplifier for processing a signal received by the avalanche photodiode 26 in addition to the signal processing circuit.

In the present embodiment, a laser diode LD has been employed as the light source. However, the light source does not necessarily perform laser oscillation because of short-distance signal transmission, and an LED may be employed.

Further, in the present embodiment, the laser diode LD has used a silicon light-emitting device so that all devices can be manufactured in a silicon-germanium process. However, a light-emitting device using a GaN-based, GaAs-based, or InP-based compound semiconductor can be used, which conforms to the light intensity and a wavelength that satisfy the product specification.

Further, the silicon waveguide 27 has been used for optical connection between the laser diode LD and the avalanche photodiode 26 of the present embodiment. However, spatial optical coupling may be employed.

### Embodiment 6

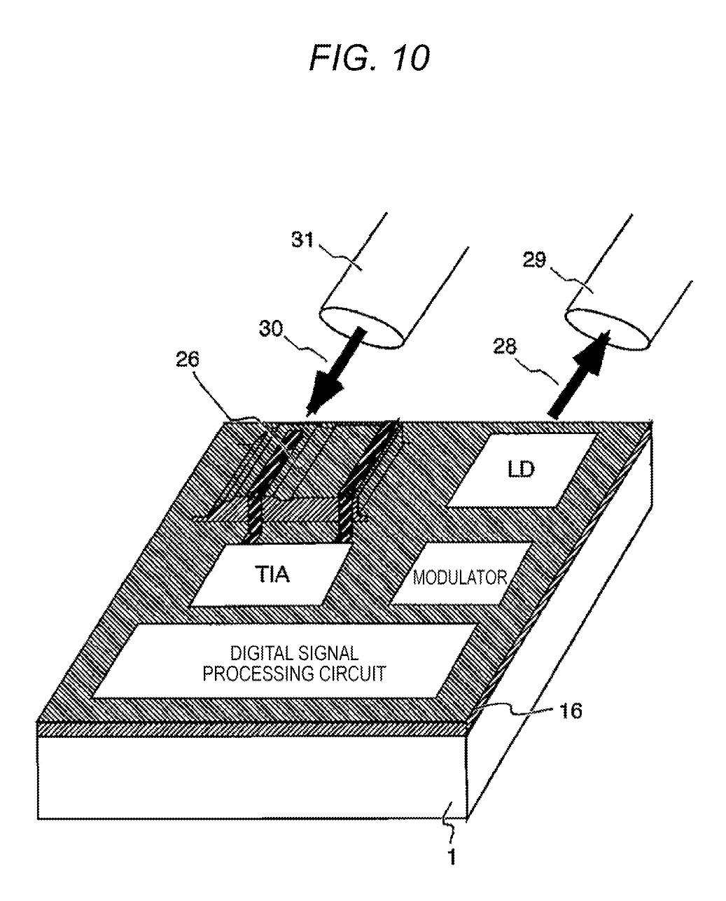

In Embodiment 6, a digital signal processing circuit and a light source are integrated on a substrate on which an avalanche photodiode 26 of Embodiment 1 or 2. FIG. 10 is a bird's-eye view of an optical communication transceiver circuit using a semiconductor photodetector (avalanche photodiode) according to the present embodiment.

Embodiment 6 is a semiconductor photodetector in which a digital signal processing circuit and a light source are integrated on a substrate on which the avalanche photodiode 26 of Embodiment 1 or 2 is formed. A different point from Embodiment 5 is that a transmitter/receiver for performing optical communication using an optical fiber is realized.

By inserting of a process to form an avalanche photodiode of Embodiment 1 or 2 into a process to forma transmitter circuit and a receiver circuit that perform signal processing, a signal processing unit and signal transmission by light are realized on the same substrate. A laser diode LD serving as a light source can be manufactured in a process to form an integrated circuit if it is a light-emitting device realized in a silicon process. However, when a light-emitting device using a compound semiconductor is used due to limitation of light intensity and wavelength, a laser diode of a compound semiconductor can be mounted.

Further, when a lens integrated avalanche photodiode and a surface emission type laser of Embodiment 4 are used in place of the light source and the avalanche photodiode 26 of Embodiments 1 and 2, an optical fiber can be arranged in a direction perpendicular to the substrate and combination can be achieved. This falls within the scope of modification of the present embodiment.

The present embodiment can be applied to an optical communication system using an optical fiber, and high performance and low cost of an optical communication system transceiver module can be achieved in addition to the effect of Embodiments 1 and 2.

### REFERENCE SIGNS LIST

1 silicon substrate
2 insulating film
3 single crystal silicon layer
4 insulating film
5 insulating film
6 insulating film
7 insulating film
8 silicon-germanium layer
9 single crystal silicon layer
10 germanium layer
11 silicon oxide film
12 p-type silicon region
13 single crystal germanium layer
14 insulating film
14 high-concentration p-type single crystal germanium layer
16 insulating film
17 high-concentration n-type silicon layer
18 p-electrode
19 n-electrode

1. A semiconductor photodetector comprising:
an insulating film formed on a substrate;
a first undoped semiconductor region and a second undoped semiconductor region provided on the insulating film;
an n-type electrode electrically connected to the first undoped semiconductor region; and
a p-type electrode electrically connected to the second undoped semiconductor region,
wherein the first undoped semiconductor region and the first undoped semiconductor region are configured from different semiconductor materials, and are arranged in a substrate in-plane direction.

2. The semiconductor photodetector according to claim 1, wherein the first undoped semiconductor region and the first undoped semiconductor region are in contact with each other in the substrate in-plane direction via a first p-type semiconductor region.

3. The semiconductor photodetector according to claim 1, wherein the first undoped semiconductor region and the first p-type semiconductor region include a first interface tapered relative to a surface of the substrate.

4. The semiconductor photodetector according to claim 3, wherein the first p-type semiconductor region and the second undoped semiconductor region include a second interface tapered relative to the surface of the substrate.

5. The semiconductor photodetector according to claim 1 being an avalanche photodiode in which the first undoped semiconductor region is a photo-absorption layer and the second undoped semiconductor region is a multiplying layer.

6. The semiconductor photodetector according to claim 1, wherein the first undoped semiconductor region is single crystal germanium, and the second undoped semiconductor region is single crystal silicon.

7. The semiconductor photodetector according to claim 1, wherein the first p-type semiconductor region includes single crystal germanium and single crystal silicon.

8. The semiconductor photodetector according to claim 1, being a surface light receiving type semiconductor photodetector.

9. The semiconductor photodetector according to claim 1, wherein a lens structure is included on a back surface of the substrate, and an optical signal is incident from the back surface of the substrate.

10. An optical receiver in which a silicon waveguide and a semiconductor photodetector are mounted on the same substrate, the semiconductor photodetector comprising:
an insulating film formed on the substrate;
a first undoped semiconductor region and a second undoped semiconductor region provided on the insulating film;
an n-type electrode electrically connected to the first undoped semiconductor region; and
a p-type electrode electrically connected to the second undoped semiconductor region,
wherein the first undoped semiconductor region and the first undoped semiconductor region are configured from different semiconductor materials, and are arranged in a substrate in-plane direction, and an optical signal is input from the silicon waveguide to the first undoped semiconductor region.

11. An optical receiver in which a semiconductor photodetector, a laser diode, and a signal processing circuit are formed on the same substrate, the semiconductor photodetector comprising:
an insulating film formed on the substrate;
a first undoped semiconductor region and a second undoped semiconductor region provided on the insulating film;
an n-type electrode electrically connected to the first undoped semiconductor region; and
a p-type electrode electrically connected to the second undoped semiconductor region,
wherein the first undoped semiconductor region and the first undoped semiconductor region are configured from different semiconductor materials, and are arranged in a substrate in-plane direction, and an optical signal is input from an optical fiber to the first undoped semiconductor region.
